(19) United States
(12) Patent Application Publication
(10) Pub. No.: US 2007/0164400 A1
(43) Pub. Date: Jul. 19, 2007

(54) SUBSTRATE STRUCTURE AND METHOD FOR FORMING PATTERNED LAYER ON SUBSTRATE STRUCTURE

(75) Inventors: Ching-Yu Chou, Hsinchu (TW); Yen-Huey Hsu, Hsinchu (TW); Wei-Yuan Chen, Hsinchu (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: ICF Technology Co., Ltd., Hsinchu (TW)

(21) Appl. No.: 11/309,689

(22) Filed: Sep. 12, 2006

(30) Foreign Application Priority Data
Jan. 13, 2006 (TW) 095101345

(51) Int. Cl. H01L 23/58

(52) U.S. Cl. 257/643

(57) ABSTRACT

A substrate structure includes a substrate and a number of banks formed on the substrate. The banks and the substrate cooperatively define a number of accommodating rooms. The accommodating rooms are configured for accommodating ink. A spread-control layer is formed on the substrate beneath the accommodating rooms. The spread-control layer enables the ink applied on the spread-control layer to spread at a lower spreading rate than the rate on the substrate without the spread-control layer formed thereon.

### FIELD OF THE INVENTION

The present invention relates to a substrate structure and a method for forming a patterned layer on the substrate structure.

### DESCRIPTION OF RELATED ART

Methods for forming a patterned layer on the substrate mainly include a photolithography method and an ink jet method.

The photolithography method includes the steps of: providing a substrate; applying a photoresist film onto the substrate; exposing the photoresist film using a photomask with a predetermined pattern; developing the photoresist film to form a patterned layer. Thus a large part of the photoresist material is wasted, the efficiency is low, and this increases the cost.

Referring to FIG. 19, the ink jet method includes the steps of: providing a substrate 301 with a plurality of banks 304, the substrate 301 and the banks 304 cooperatively defining a plurality of accommodating rooms; jetting ink 314 into the accommodating rooms on the substrate 301; solidifying the ink 314 to form a patterned layer. In the inkjet method, the efficiency of the material is increased. Thus the inkjet method decreases the cost.

In the ink jet method, the ink 314 is still in a liquid state when the ink 314 is jetted into the accommodating rooms. When the ink 314 contacts with the banks 304, the ink 314 climbs up along the banks 304 because of the force driven by surface energy difference between the ink 314 and the banks 304. This leads to the small contact angle θ between the ink 314 and the banks 304. When the ink 314 is solidified, the patterned layer has uneven thicknesses.

It is therefore desirable to find a new substrate structure and a new method which can overcome the above mentioned problems.

### SUMMARY OF THE INVENTION

In a preferred embodiment, a substrate structure includes a substrate and a plurality of banks formed on the substrate. The banks and the substrate cooperatively define a plurality of accommodating rooms. The accommodating rooms are configured for accommodating ink. A spread-control layer is formed on the substrate in the accommodating rooms. The spread-control layer enables the ink to spread at a lower spreading rate than the rate on the substrate without the spread-control layer formed thereon.

Other advantages and novel features will become more apparent from the following detailed description of the present substrate structure and the present method, when taken in conjunction with the accompanying drawings.

### BRIEF DESCRIPTION OF THE DRAWINGS

Many aspects of the present substrate structure and the present method can be better understood with reference to the following drawings. The components in the drawings are not necessarily drawn to scale, the emphasis instead being placed upon clearly illustrating the principles of the present invention.

FIG. 1 is a schematic cross-sectional view of a substrate structure in accordance with a first embodiment;

FIG. 2 is a schematic cross-sectional view of a substrate structure in accordance with a second embodiment;

FIG. 3 is a schematic cross-sectional view of a substrate structure in accordance with a third embodiment;

FIG. 4 is a schematic cross-sectional view of a substrate structure in accordance with a fourth embodiment;

FIG. 5 is a schematic cross-sectional view of a substrate structure in accordance with a fifth embodiment;

FIG. 6 is a flow chart of a method for forming a patterned layer on the substrate structure;

FIGS. 7 and 8 are schematic cross-sectional views illustrating successive stages of a method for manufacturing the substrate structure of the first embodiment;

FIGS. 9 to 11 are schematic cross-sectional views illustrating successive stages of a method for manufacturing the substrate structure of the second embodiment;

FIGS. 12 to 14 are schematic cross-sectional views illustrating successive stages of another method for manufacturing the substrate structure of the second embodiment;

FIGS. 15 to 18 are schematic cross-sectional views illustrating successive stages of a method for forming a patterned layer on the substrate structure of the first embodiment;

FIG. 19 is a schematic cross-sectional view of a typical substrate structure.

Corresponding reference characters indicate corresponding parts throughout the drawings. The exemplifications set out herein illustrate at least one preferred embodiment of the invention, in one form, and such exemplifications are not to be construed as limiting the scope of the invention in any manner.

### DETAILED DESCRIPTION OF THE INVENTION

Reference will now be made to the drawings to describe the preferred embodiments of the present substrate structure and the present method in detail.

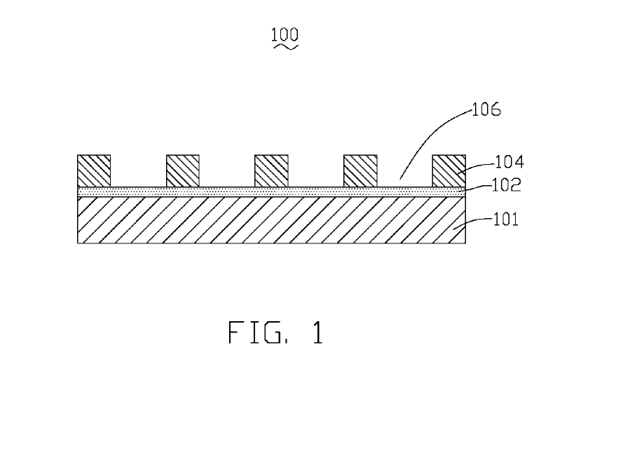

Referring to FIG. 1, a substrate structure 100 is shown in accordance with a first embodiment. The substrate structure 100 includes a substrate 101, a spread-control layer 102 formed on the substrate 101, and a plurality of banks 104 formed on the spread-control layer 102. The substrate 101 and the banks 104 cooperatively define a plurality of accommodating rooms 106. The accommodating rooms 106 are configured for accommodating ink.

The material of the substrate 101 is selected from the group consisting of: glass, quartz glass, silicon, metal, and plastic. The substrate 101 is made of glass in the first embodiment. The banks are formed on the spread-control layer by photolithography.

The spread-control layer 102 enables the ink to spread at a lower spreading rate than the rate on the substrate 101 without the spread-control layer 102 formed thereon. The spread-control layer 102 may also enable the ink to spread over a smaller spreading area than the corresponding spreading area on the substrate 101 without the spread-control layer 102 formed thereon.

The material of the spread-control layer 102 is surfactants, polymer material, or other suitable material. The surfactant can be, for example, cationic surfactant, anionic surfactant, or nonionic surfactant. The cationic surfactant is, for example, quaternary ammonium salts, or amine salts. The anionic surfactant is, for example, ether carboxylates, sulfates, or sulfonantes. The nonionic surfactant is, for example, alchol ethoxylates, nonylphenol ethoxylates, octylphenol ethoxylates, sorbitan esters, siloxane surfactants, or fluorosurfactants. The polymer material is, for example, siloxane polymer, acrylic polymer, epoxy polymer, or polyester polymer.

After the ink is jetted into the accommodating rooms 106, the spread-control layer 102 decreases the spreading rate or the spreading area of the ink. During the spreading process, the solid content of the ink increases due to the evaporation of the ink solvent. Therefore, the spreading rate of the ink is further decreased. When the ink spreads and contacts with the banks 104, the ink becomes quite viscous and is difficult to climb up along the banks 104. Therefore, the contact angle between the ink and the banks 104 is increased. When the ink is solidified, the patterned layer has even thicknesses and smooth surface.

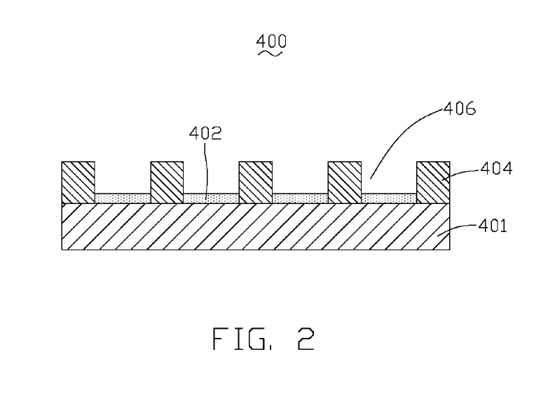

Referring to FIG. 2, a substrate structure 400 is shown in accordance with a second embodiment. The substrate structure 400 is similar to the substrate structure 100. However, the spread-control layer 402 is formed on the substrate 401 beneath the accommodating room 406 but not on the substrate 401 beneath the bank 404.

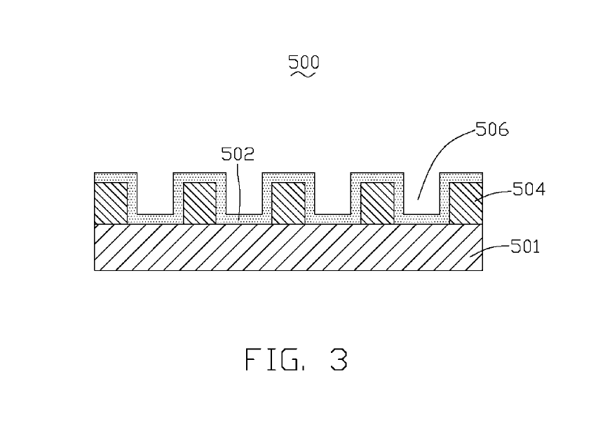

Referring to FIG. 3, a substrate structure 500 is shown in accordance with a third embodiment. The substrate structure 500 is similar to the substrate structure 400, but the spread-control layer 502 is also formed covering the bank 504.

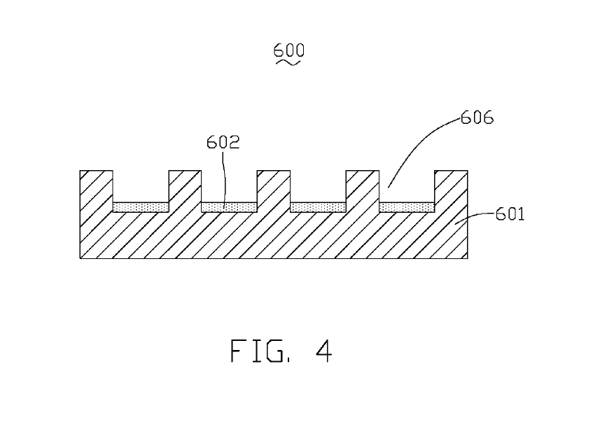

Referring to FIG. 4, a substrate structure 600 is shown in accordance with a fourth embodiment. The substrate structure 600 includes a substrate 601. The substrate 601 has a plurality of grooves 606 defined therein. The grooves 606 are used as accommodating rooms for accommodating ink. A spread-control layer 602 is formed at the bottom of the accommodating rooms. The grooves 606 can be formed using a photo-mask (not shown) by a lasing process, a sand blasting process, or an etching process. Also the grooves 504 can be formed by laser process or sand blasting process with a help of an accurate positioning mechanism. The spread-control layer 602 can be formed using a method selected from the group consisting of: dry film lamination, wet spin coating, wet slit coating, and screening printing.

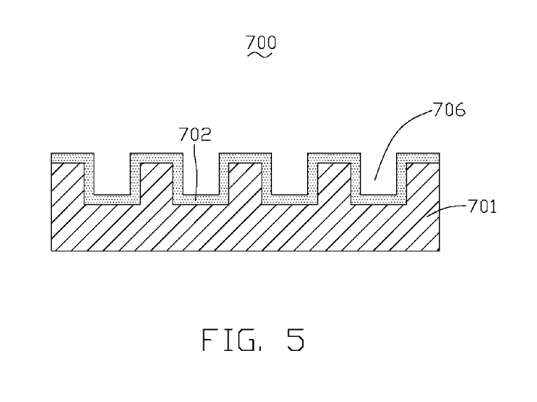

Referring to FIG. 5, a substrate structure 700 is shown in accordance with a fifth embodiment. The substrate structure 700 is similar to the substrate structure 600, but the spread-control layer 602 is formed on a whole surface of the substrate 701.

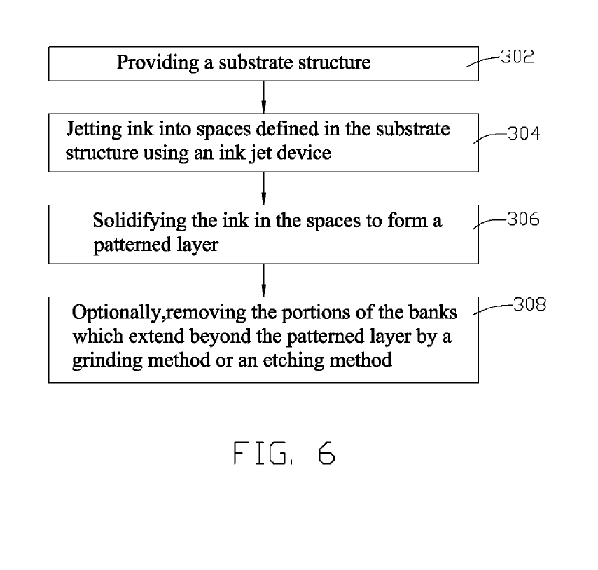

Referring to FIG. 6, a flowchart of a method of forming a patterned layer on the substrate structure is shown. The method mainly includes the following steps: providing a substrate structure (step 302); jetting ink into accommodating rooms defined in the substrate structure using an ink jet device (step 304); solidifying the ink in the accommodating rooms to form a patterned layer (step 306); optionally, removing portions of the banks which extend beyond the patterned layer using a grinding method or an etching method (step 308).

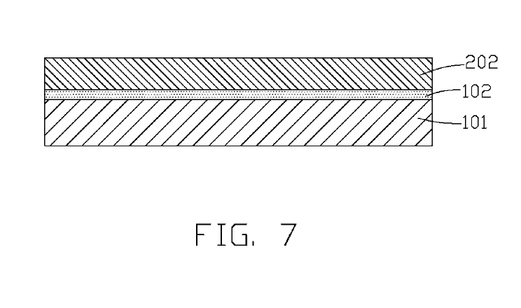

With references of FIGS. 7 to 18, the method for forming a patterned layer on the substrate structure is described in more detail.

In step 302, a substrate structure is provided, referring to FIGS. 1 to 5. The substrate structure can be the substrate structure 100, the substrate structure 400, the substrate structure 500, the substrate structure 600, or the substrate structure 700.

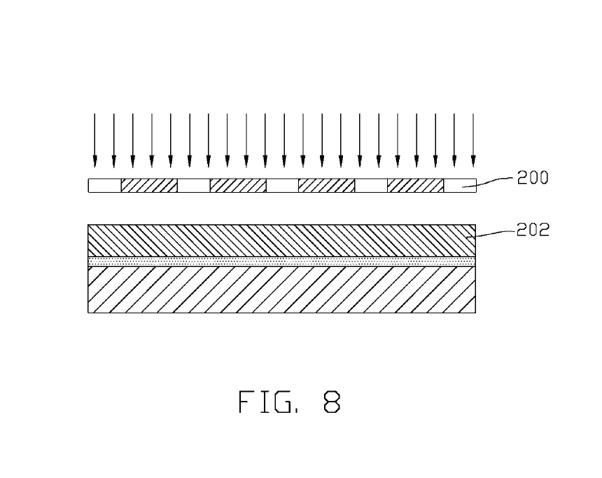

The method of manufacturing the substrate structure 100 (referring to FIG. 1) in accordance with a first embodiment includes the steps of: providing a substrate 101; forming a spread-control layer 102 on the substrate 101 using a method selected from the group consisted of dry film lamination, wet spin coating, and wet slit coating; solidifying the spread-control layer 102 using a device selected from the group consisting of heating devices and light-exposure devices to finish forming the spread-control layer 102; referring to FIG. 7, forming a negative photoresist film 202 on the spread-control layer 102 using a method selected from the group consisting of: dry film lamination, wet spin coating, and wet slit coating; exposing the photoresist film 202 using a photomask 200 with a predetermined pattern, referring to FIG. 8; developing the photoresist film 202 to form a plurality of banks 104 on the spread-control layer 102, referring to FIG. 1.

The method above forms a plurality of banks 104 on the spread-control layer 102 using the negative photoresist film 202. It should be noted that a positive photoresist film can be also used to form the banks 104.

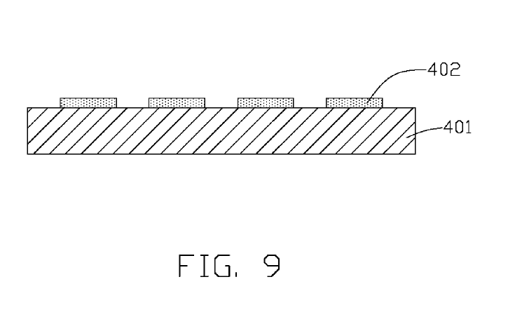

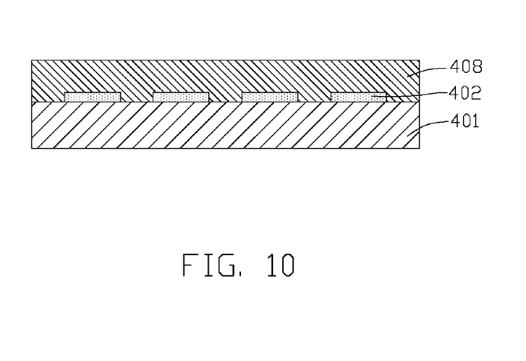

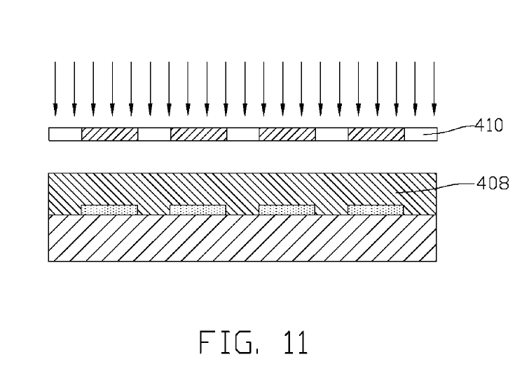

The first method of manufacturing the substrate structure 400 (referring to FIG. 2) in accordance with a second embodiment includes the steps of: providing a substrate 401; forming a spread-control layer 402 on the substrate 401 using screen printing method, referring to FIG. 9; solidifying the spread-control layer 402 using a device selected from the group consisting of heating devices and light-exposure devices to finish forming the spread-control layer 402; forming a negative photoresist film 408 on the substrate 401 covering the spread-control layer pattern 402, referring to FIG. 10; exposing the photoresist film 408 using a photomask 410 with a predetermined pattern corresponding to the spread-control layer pattern 402, referring to FIG. 11; developing the photoresist film 408 to form a plurality of banks 404 on the substrate 401, referring to FIG. 2.

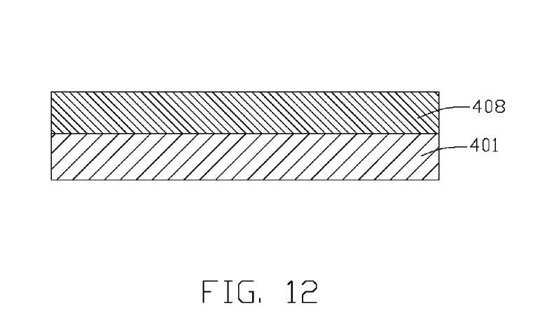

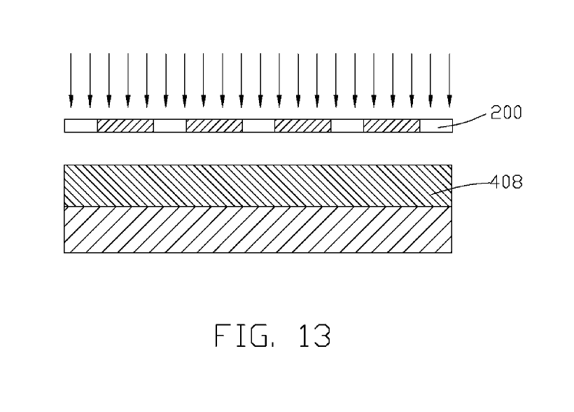

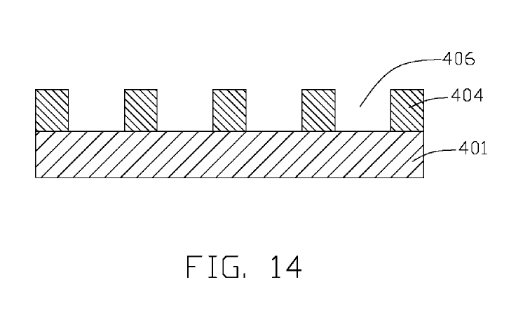

The second method of manufacturing the substrate structure 400 (referring to FIG. 2) in accordance with a second embodiment includes the steps of: providing a substrate 401; forming a negative photoreseist film 408 on the substrate 401, referring to FIG. 12; exposing the photoresist film 408 using a photomask 200 with a predetermined pattern, referring to FIG. 13; developing the photoresist film 408 to form a plurality of banks 404 on the substrate 401, where the banks 404 and the substrate 401 cooperatively define a plurality of accommodating rooms 406, referring to FIG. 14; forming a spread-control layer 402 on the substrate 401 in the accommodating rooms 406 using a method selected from the group consisting of: dry film lamination, wet spin coating, wet slit coating, and screening printing; solidifying the spread-control layer 402 using a device selected from the group consisting of heating devices and light-exposure devices, referring to FIG. 2.

The two methods above form a plurality of banks 404 on the substrate 401 using the negative photoresist film. It should be noted that a positive photoresist film can be also used to form the banks 404.

Steps 304 to 308 will be described in more detail accompanying the substrate structure 100 (referring to FIG. 1) in accordance with the first embodiment. It should be noted that the substrate structure 400 can be also used to manufacture the patterned layer similar to the substrate structure 100.

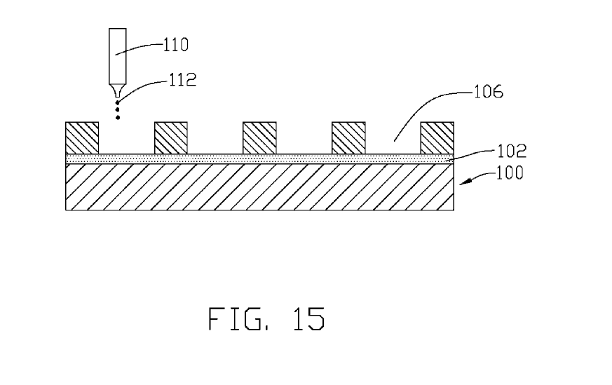

In step 304, ink 112 is jetted into the accommodating rooms 106 using an ink jet device 110, referring to FIG. 15. The ink 112 is made of the material of the patterned layer. The ink jet device 110 is, for example, a thermal bubble ink jet device, or a piezoelectric ink jet device.

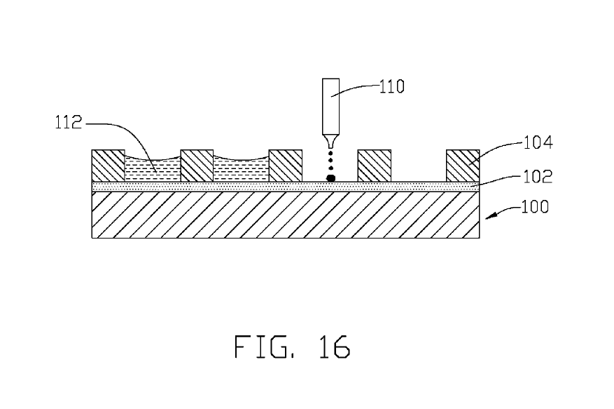

Referring to FIG. 16, after the ink 112 is jetted into the accommodating rooms 106, the spread-control layer 102 decreases the spreading rate or the spreading area of the ink 112. During the spreading process, the solid content of the ink 112 increases due to the evaporation of the ink solvent. Therefore, the spreading rate of the ink 112 is further decreased. When the ink spreads and contacts with the banks 104, the ink 112 becomes quite viscous and is difficult to climb up along the banks 104 and the contact angle between the ink 112 and the banks 104 is increased.

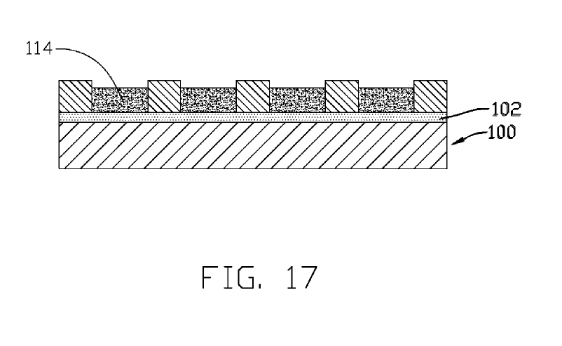

In step 306, the ink 112 is solidified in the accommodating rooms 106 to form a patterned layer 114, referring to FIG. 17. The ink 112 is solidified using at least one device chosen from the group consisting of vacuumizing devices, heating devices and light-exposure devices. The light-exposure devices include ultraviolet light-exposure devices.

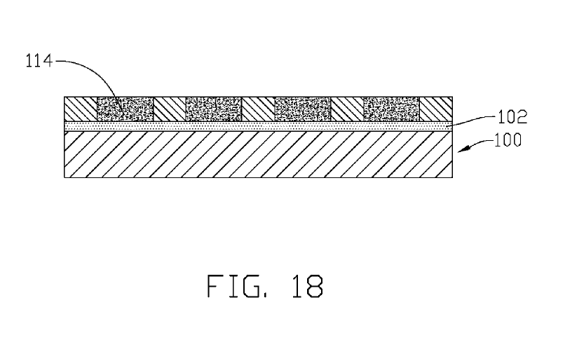

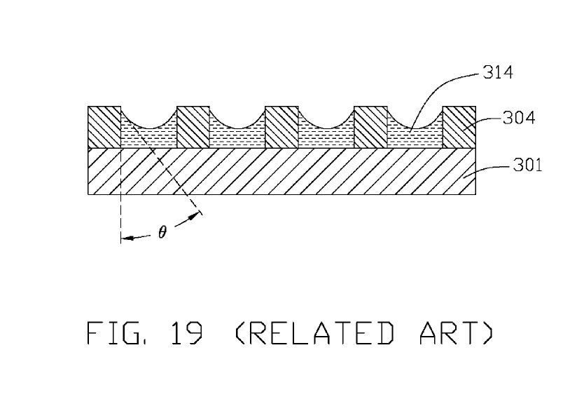

In optional step 308, portions of the banks 104 which extend beyond the patterned layer 114 are removed using either a grinding method or an etching method so as to obtain a smooth surface, referring to FIG. 18.

Each substrate structures in accordance with each embodiment includes a spread-control layer. After the ink is jetted into the accommodating rooms, the spread-control layer decreases the spreading rate or the spreading area of the ink. During the spreading process, the solid content of the ink increases due to the evaporation of the ink solvent. Therefore, the spreading rate of the ink is further decreased. When the ink spreads and contacts with the banks, the ink becomes quite viscous and is difficult to climb up along the banks. Therefore, the contact angle between the ink and the banks is increased. Using the substrate structure in accordance with the first and second embodiments, the method forms a patterned layer having even thicknesses and smooth surface.

It should be noted that the method of forming a patterned layer on a substrate structure can be used to manufacture devices such as, for example, color filters and organic light emitting display devices. In the manufacturing of color filters, the method can be used to manufacture RGB (Red, Green, and Blue) color layers. Correspondingly, the bank mentioned above can include single layer bank (using black matrix only as the bank), or multi-layer bank (using black matrix and one or more top layers on the black matrix as the bank). In the manufacturing of an organic light emitting display device, the method can be used to manufacture, for example, emission-material layers, electron-transfer layers, hole-transfer layers and electron-ejection layers.

Although the present invention has been described with reference to specific embodiments, it should be noted that the described embodiments are not necessarily exclusive, and that various changes and modifications may be made to the described embodiments without departing from the scope of the invention as defined by the appended claims.

What is claimed is:

1. A substrate structure, comprising:
a substrate;
a plurality of banks formed on the substrate, the banks and the substrate cooperatively defining a plurality of accommodating rooms, the accommodating rooms being configured for accommodating ink; and
a spread-control layer formed on the substrate beneath the accommodating rooms, the spread-control layer enabling the ink applied on the spread-control layer to spread at a lower spreading rate than the rate on the substrate without the spread-control layer formed thereon.

2. The substrate structure as claimed in claim 1, wherein the material of the spread-control layer is selected from the group consisting of surfactants and polymer material.

3. The substrate structure as claimed in claim 1, wherein the material of the substrate is selected from the group consisting of glass, quartz glass, silicon, metal and plastic.

4. The substrate structure as claimed in claim 1, wherein the spread-control layer is formed covering the banks.

5. A substrate structure, comprising:
a substrate;
a plurality of banks formed on the substrate, the banks and the substrate cooperatively defining a plurality of accommodating rooms, the accommodating rooms being configured for accommodating ink; and
a spread-control layer formed on the substrate beneath the accommodating rooms, the spread-control layer enabling the ink applied on the spread-control layer to spread over a smaller spreading area than the area on the substrate without the spread-control layer formed thereon.

6. The substrate structure as claimed in claim 5, wherein the material of the spread-control layer is selected from the group consisting of surfactants and polymer material.

7. The substrate structure as claimed in claim 5, wherein the material of the substrate is selected from the group consisting of glass, quartz glass, silicon, metal and plastic.

8. The substrate structure as claimed in claim 5, wherein the spread-control layer is formed covering the banks.

9. A method for forming a patterned layer on the substrate structure, comprising the steps of:
providing a substrate structure as claimed in claim 1;
jetting ink into the accommodating rooms using an ink jet device; and
solidifying the ink in the accommodating rooms to form the patterned layer on the substrate structure.

10. The method as claimed in claim 9, wherein the substrate structure is made by a method comprising the steps of:
providing a substrate;
forming a spread-control layer on the substrate using a method selected from the group consisting of dry film lamination, wet spin coating and wet slit coating;
solidifying the spread-control layer;
forming a photoresist film on the spread-control layer;
exposing the photoresist film using a photomask with a predetermined pattern; and
developing the photoresist film to form a plurality of banks on the spread-control layer.

11. The method as claimed in claim 10, wherein the spread-control layer is solidified using a device selected from the group consisting of heating devices and light-exposure devices.

12. The method as claimed in claim 9, wherein the substrate structure is made by a method comprising the steps of:
providing a substrate;
forming a spread-control layer on the substrate by screen printing;
solidifying the spread-control layer;
forming a photoresist film on the substrate covering the spread-control layer;
exposing the photoresist film using a photomask with a predetermined pattern; and
developing the photoresist film to form a plurality of banks on the substrate.

13. The method as claimed in claim 12, wherein the spread-control layer is solidified using a device selected from the group consisting of heating devices and light-exposure devices.

14. The method as claimed in claim 9, wherein the substrate structure is made by a method comprising the steps of:
providing a substrate;
forming a photoresist film on the substrate;
exposing the photoresist film using a photomask with a predetermined pattern;
developing the photoresist film to form a plurality of banks on the substrate, the banks and the substrate cooperatively defining a plurality of accommodating rooms; and
forming a spread-control layer on the substrate in the accommodating rooms.

15. The method as claimed in claim 9, wherein the inkjet device is selected from the group consisting of a thermal bubble ink jet device and a piezoelectric ink jet device.

16. The method as claimed in claim 9, wherein the ink is solidified using at least one solidifying device selected from the group consisting of the vacuumizing devices, heating devices and light-exposure devices.

17. The method as claimed in claim 16, wherein the light-exposure devices comprise ultraviolet light-exposure devices.

18. The method as claimed in claim 9, further comprising the following step after the ink is solidified:
removing portions of the banks which extend beyond the patterned layer through grinding or etching.

19. The method as claimed in claim 14, wherein the spread-control layer is formed using a method selected from the group consisting of: dry film lamination, wet spin coating, wet slit coating, and screening printing.

20. The method as claimed in claim 14, further comprising the following step after the
spread-control layer is formed: solidifying the spread-control layer using a device selected from the group consisting of heating devices and light-exposure devices.

21. A substrate structure, comprising:
a substrate with a plurality of grooves defined in a surface, the grooves being used as accommodating rooms for accommodating ink; and
a spread-control layer formed on the substrate at the bottom of the accommodating rooms, the spread-control layer enabling the ink applied on the spread-control layer to spread at a lower spreading rate than the rate on the substrate without the spread-control layer formed thereon.

22. A method for forming a patterned layer on the substrate structure, comprising the steps of:
providing a substrate structure as claimed in claim 21;
jetting ink into the accommodating rooms using an ink jet device; and
solidifying the ink in the accommodating rooms to form a patterned layer on the substrate structure.
